(19) United States
(12) Patent Application Publication
(10) Pub. No.: US 2010/0200881 A1
(43) Pub. Date: Aug. 12, 2010

(54) Light Emitting Element and Illumination Device

(75) Inventor: Katsuaki Masaki, Kyoto (JP)

Correspondence Address: Hogan Lovells US LLP, 1999 AVENUE OF THE STARS, SUITE 1400, LOS ANGELES, CA, 90067, US

(73) Assignee: KYOCERA CORPORATION, Kyoto-shi, Kyoto (JP)

(21) Appl. No.: 12/667,001

(22) PCT Filed: Mar. 27, 2008
(86) PCT No.: PCT/JP2008/055967

§ 371 Date: Dec. 28, 2009

(30) Foreign Application Priority Data
Jun. 28, 2007 (JP) 2007-171014

(51) Int. Cl. H01L 33/02; H01L 33/50; H01L 33/42

(52) U.S. Cl. 257/98; 257/103; 257/E33.023; 257/E33.061; 257/E33.067; 257/E33.064

(57) ABSTRACT

A light emitting element comprises a semiconductor layer (8) in which a first conductive-type gallium nitride-based compound semiconductor layer (8a), a light emitting layer (8b) composed of a gallium nitride-based compound semiconductor, and a second conductive-type gallium nitride-based compound semiconductor layer (8c) are laminated; and a porous transparent conductive layer (20) that has a porosity becoming higher in a thickness direction thereof from a side of the semiconductor layer (8) or a transparent conductive layer (20) that has a refractive index becoming lower in a thickness direction thereof from a side of the semiconductor layer (8), the transparent conductive layer (20) being formed on a main surface of the semiconductor layer (8). By this structure, a light emitting element that enables to dramatically improve light extraction efficiency can be obtained.

### TECHNICAL FIELD

The present invention relates to a light emitting element and an illumination device.

### BACKGROUND ART

Recently, light emitting elements that emit light in a range of from ultraviolet light to blue light have been attracting attention.

This sort of light emitting element using a galliùm nitride-based compound semiconductor can emit white light when combined with a fluorescent substance, and consume less energy and have a long life. Thus, these light emitting elements have shown great promise as a substitute for incandescent electric lamps and fluorescent lamps, and have been put into practice. However, the light-emitting efficiency of a light emitting element using a gallium nitride-based compound semiconductor is lower than that of a fluorescent lamp, and thus, improvements in the efficiency are required, and various studies have been conducted to achieve this object (see Patent Citation 1, for example).

FIG. 3 shows a cross-sectional view of an example of a conventional light emitting element. A semiconductor layer 2 composed of an n-type gallium nitride-based compound semiconductor layer 2a, a light emitting layer 2b composed of a gallium nitride-based compound semiconductor layer, and a p-type gallium nitride-based compound semiconductor layer 2c is formed on a substrate 1, and an n-type electrode 3 and a p-type electrode 4 are respectively formed on the n-type gallium nitride-based compound semiconductor layer 2a and the p-type gallium nitride-based compound semiconductor layer 2c. A conductive layer transparent to emitted light is used as the p-type electrode 4, and is formed on the entire upper surface of the p-type gallium nitride-based compound semiconductor layer 2c in order to uniformly diffuse current through the p-type gallium nitride-based compound semiconductor layer 2c. An n-type pad electrode 5 and a p-type pad electrode 6 are respectively arranged on the n-type electrode 3 and part of the p-type electrode 4 in order to inject a current from the outside, and are connected to wires or the like of a package by wire bonding. Furthermore, a sapphire substrate is generally used as the substrate 1 that is used to form the gallium nitride-based compound semiconductor layers.

Patent Citation 1: Japanese Examined Patent Publication JP-B2 3026087

Patent Citation 2: Japanese Unexamined Patent Publication JP-A 2005-259970

Non Patent Citation 1: APPLIED.PHYSICS.LETTERS.86.221101 (2005)

### DISCLOSURE OF INVENTION

### Technical Problem

In the conventional light emitting element in FIG. 3, when the wavelength of light emitted by the light emitting layer 2b is taken as 400 nm, the refractive index of the substrate 1 made of sapphire is approximately 1.78, but the refractive index of the gallium nitride-based compound semiconductor is as high as approximately 2.55. Accordingly, in light emitted by the light emitting layer 2b, light that is incident on the substrate 1 made of sapphire at an incident angle of greater than approximately 44° (θᵣ=arc sin(1.78/2.55)), which is the critical angle θᵣ, is repeatedly totally reflected inside the semiconductor layer 2 in which the gallium nitride-based compound semiconductor layers are laminated. Accordingly, most of the light is absorbed by the semiconductor layer 2 while being repeatedly totally reflected inside the semiconductor layer 2, and the other light is radiated from an end portion of the semiconductor layer 2 to the outside, and thus, there is a problem in that the amount of light emitted is reduced.

Moreover, in the case where the external environment of the semiconductor layer 2 is air (refractive index≈1), the difference in refractive index between these media further increases, the amount of light reflected at the boundary therebetween toward the semiconductor layer 2 further increases, and thus, the light extraction efficiency is further reduced.

The invention has been completed in view of the above-described problem of the conventional technique, and an object thereof is to obtain a light emitting element that enables to dramatically improve light extraction efficiency.

### Technical Solution

A light emitting element according to a first embodiment of the invention comprises:

a semiconductor layer in which a first conductive-type gallium nitride-based compound semiconductor layer, a light emitting layer composed of a gallium nitride-based compound semiconductor, and a second conductive-type gallium nitride-based compound semiconductor layer are laminated; and

a porous transparent conductive layer that is formed on a main surface of the semiconductor layer and that has a porosity becoming higher in a thickness direction thereof from a side of the semiconductor layer.

An illumination device according to a first embodiment of the invention comprises:

the light emitting element according to the first embodiment; and

at least one of a fluorescent substance and a phosphorescent substance that emit light based upon receiving light emitted by the light emitting element.

Furthermore, a light emitting element according to a second embodiment of the invention comprises:

a semiconductor layer in which a first conductive-type gallium nitride-based compound semiconductor layer, a light emitting layer composed of a gallium nitride-based compound semiconductor, and a second conductive-type gallium nitride-based compound semiconductor layer are laminated; and

a transparent conductive layer that is formed on a main surface of the semiconductor layer and that has a refractive index becoming lower in a thickness direction thereof from a side of the semiconductor layer.

An illumination device according to a second embodiment of the invention comprises:

the light emitting element according to the second embodiment; and

at least one of a fluorescent substance and a phosphorescent substance that emit light based upon receiving light emitted by the light emitting element.

Furthermore, a light emitting element according to a third embodiment of the invention comprises:

a light emitting portion; and

a porous transparent conductive layer that is formed on a light-radiating surface of the light emitting portion and that has a porosity becoming higher in a thickness direction thereof from a side of the light emitting portion.

Furthermore, a light emitting element according to a fourth embodiment of the invention comprises:

a light emitting portion; and

a transparent conductive layer that is formed on a light-radiating surface of the light emitting portion and that has a refractive index becoming lower in a thickness direction thereof from a side of the light emitting portion.

### ADVANTAGEOUS EFFECTS

According to the light emitting element and the illumination device of the invention, the light extraction efficiency can be improved.

### BRIEF DESCRIPTION OF THE DRAWINGS

FIGS. 1(a) and 1(b) are respectively cross-sectional views showing examples of light emitting elements of this embodiment.

FIGS. 2(a) and 2(b) are respectively cross-sectional views showing other examples of the light emitting elements of this embodiment.

FIG. 3 is a cross-sectional view showing an example of a conventional light emitting element.

FIG. 4a is an enlarged cross-sectional photograph of a transparent conductive layer in the light emitting element of this embodiment having a transparent conductive layer made of an aggregate of nanowire-shaped crystals.

FIG. 4b is an enlarged plan photograph of a transparent conductive layer in the light emitting element of this embodiment having a transparent conductive layer made of an aggregate of nanowire-shaped crystals.

### BEST MODE FOR CARRYING OUT THE INVENTION

### Light Emitting Element

Hereinafter, a light emitting element according to embodiments of the invention will be described in detail with reference to the drawings. Here, the invention is not limited to the following examples, and, for example, various modifications and improvements are possible within a range not departing from the gist of the invention without causing any problem.

### First Embodiment

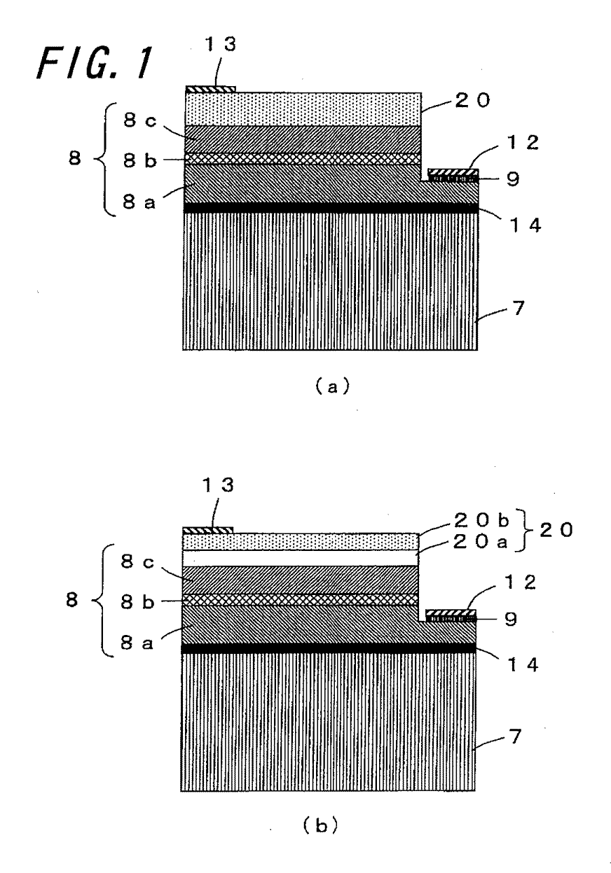

FIGS. 1(a) and 1(b) are schematic cross-sectional views showing examples of a light emitting element (light emitting diode: LED) of this embodiment. In FIGS. 1(a) and 1(b), reference numeral 7 denotes a substrate made of sapphire or the like, reference numeral 8 denotes a semiconductor layer (laminated member) in which a plurality of gallium nitride-based compound semiconductor layers are laminated, reference numeral 8a denotes a first conductive-type (n-type) gallium nitride-based compound semiconductor layer, reference numeral 8b denotes a light emitting layer composed of a gallium nitride-based compound semiconductor layer, reference numeral 8c denotes a second conductive-type (p-type) gallium nitride-based compound semiconductor layer, reference numeral 9 denotes a first conductive-type conductive layer that is used as a first conductive-type electrode or that is used to form a first conductive-type electrode, reference numeral 20a denotes a first transparent conductive layer forming a second conductive-type conductive layer that is used as a second conductive-type electrode or that is used to form a second conductive-type electrode, reference numeral 20b denotes a second transparent conductive layer, and reference numeral 20 denotes a transparent conductive layer.

The gallium nitride-based compound semiconductor or the nitride semiconductor in this embodiment is represented by the chemical formula AlₓGa_{y}In_{1-x-y}N (0≦x>1, 0≦y≦1, 0≦x+y≦1) or the like.

As shown in FIG. 1(a), the light emitting element of this embodiment includes the semiconductor layer 8 in which the first conductive-type gallium nitride-based compound semiconductor layer 8a, the light emitting layer 8b composed of a gallium nitride-based compound semiconductor, and the second conductive-type gallium nitride-based compound semiconductor layer 8c are laminated, and the porous transparent conductive layer 20 that is formed on a main surface of the semiconductor layer 8 and that has a porosity becoming higher in the thickness direction thereof from the side of the semiconductor layer 8.

With the above-described configuration, the refractive index of the transparent conductive layer 20 is gradually becoming lower in the thickness direction thereof from the side of the semiconductor layer 8. As a result, the refractive index can be gradually becoming lower in the thickness direction in the entire transparent conductive layer 20 and can be close to the refractive index of air, the reflection of light at an interface between media having different refractive indexes is reduced, and the light extraction efficiency can be improved.

The refractive index of the transparent conductive layer 20 is difficult to directly evaluate using a method, such as a spectroscopic ellipsometry method, because the surface of the transparent conductive layer 20 is not flat. Accordingly, it can be substantially judged that the refractive index of the transparent conductive layer 20 is gradually becoming lower in the thickness direction thereof from the side of the semiconductor layer 8 in the case where the transmission of light that passes through the transparent conductive layer 20 is measured and the transmission is higher than that of a transparent conductive layer in which the refractive index is constant in the thickness direction.

Furthermore, when the thickness of the transparent conductive layer 20 is reduced by subjecting the surface thereof to a grinding method, an etching method, or the like, and the transmissions of the transparent conductive layer 20 at the respective thicknesses are measured, the refractive index of the transparent conductive layer 20 can be specified.

Here, specifically, the spectroscopic ellipsometry method is a method in which a change in the polarized state of light reflected by the surface of a sample is measured, and the refractive index is obtained by fitting analysis.

Furthermore, it is preferable that the transparent conductive layer 20 is made of an aggregate of nanowire-shaped crystals. In this case, the size of pores (the size of gaps between the nanowire-shaped crystals) and the porosity can be controlled by controlling the shape, the size, and the number (density) of the nanowire-shaped crystals.

The aggregate of nanowire-shaped crystals is formed in the following manner.

In the case where a transparent conductive layer 20 composed of an ITO layer or the like is formed by an electron-beam evaporation method, in a state where the temperature of the substrate 7 is increased without introducing a gas into the electron beam evaporation apparatus, electron beam evaporation of the transparent conductive layer 20 is performed. Accordingly, anisotropy appears in the crystal growth rate of metal oxide crystals forming the transparent conductive layer 20, the metal oxide crystals have a large aspect ratio, and thus, gaps are formed when the metal oxide crystals are deposited. In the case where the size of the gaps is the wavelength of light or smaller, the ratio of the gaps increases as the aspect ratio of metal oxide crystals increases, and thus, the refractive index is becoming lower as the aspect ratio increases. Accordingly, when the temperature of the substrate 7 is continuously increased from the initial stage in the formation of the transparent conductive layer 20, a transparent conductive layer 20 in which the refractive index is becoming lower in the thickness direction can be obtained.

Moreover, in a state where the aspect ratio of the metal oxide crystals is increased, when the layer is formed finally at a temperature of approximately 400° C., the metal oxide crystals are formed into nanowire-shaped crystals having a diameter of 20 nm or less and a length of 500 nm or more. Then, when the size of the gaps between the nanowire-shaped crystals is substantially the same as or not smaller than the wavelength of light, the light is refracted at the gaps, and thus, the transparent conductive layer 20 scatters the light. The thus formed transparent conductive layer 20 is reduced and partially becomes a metal (In, etc.), and the transmission is lowered. Thus, lastly, an oxidation treatment is performed in an atmospheric atmosphere at 600° C. for approximately 5 minutes.

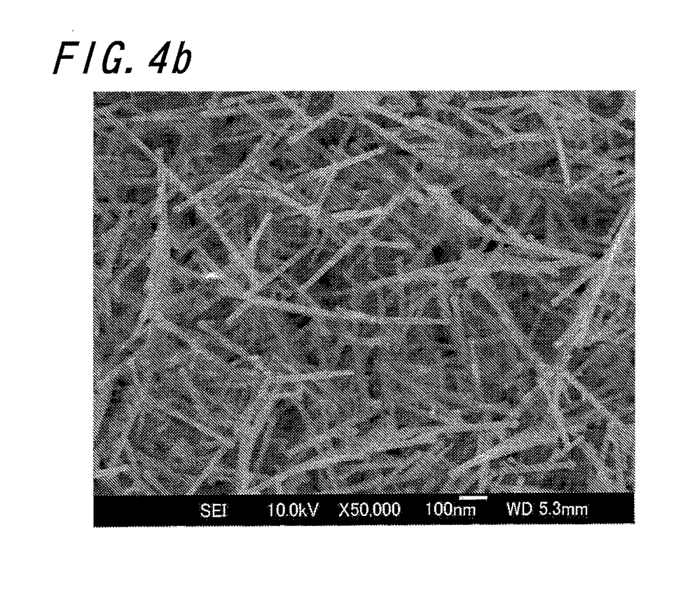

Here, as shown in the enlarged cross-sectional photograph in FIG. 4(a) and the enlarged plan photograph in FIG. 4(b), the aggregate of nanowire-shaped crystals is such that a large number of nanowire-shaped crystals grow and are deposited so that their longitudinal directions lie in random directions.

Furthermore, as shown in FIG. 1(b), the transparent conductive layer 20 may includes the first transparent conductive layer 20a that is formed on the side of the semiconductor layer 8 and that is made of an aggregate of conductive fine particles and the second transparent conductive layer 20b that is formed on the first transparent conductive layer 20a and that is made of an aggregate of nanowire-shaped crystals.

As described above, the transparent conductive layer 20 including the first transparent conductive layer 20a and the second transparent conductive layer 20b can be formed by continuously increasing the temperature of the substrate 7 during the formation of the transparent conductive layer 20 by an electron-beam evaporation method. For example, the first transparent conductive layer 20a and the second transparent conductive layer 20b composed of an ITO layer can be formed by setting the temperature of the substrate 7 to room temperature at the initial stage in the formation and to 400° C. at an end stage of the formation. Then, after the formation, an oxidation treatment is performed in an atmospheric atmosphere at 600° C. for approximately 5 minutes. In this case, directly after the formation of the first transparent conductive layer 20a, the second transparent conductive layer 20b can be successively formed. In this case, the porosity of the first transparent conductive layer 20a is becoming higher in the thickness direction thereof from the side of the semiconductor layer 8.

It is preferable that the material of the transparent conductive layer 20 is oxide of at least one of zinc, indium, tin, and magnesium. In this case, the transparent conductive layer 20 has a high transmission from ultraviolet light to blue light, and has good ohmic contact with a p-type gallium nitride-based compound semiconductor layer.

More specifically, the transparent conductive layer 20 is preferably made of a metal oxide-based substance, such as indium tin oxide (ITO), stannic oxide (SnO₂), zinc oxide (ZnO), or the like. Among these substances, indium tin oxide (ITO) is particularly preferable because the transmission from ultraviolet light to blue light is high, and the ohmic contact with the p-type gallium nitride-based compound semiconductor layer 8c is good. The transparent conductive layer 20 can be formed using an electron-beam evaporation method or a sol-gel method.

Furthermore, the light emitting element (LED) of this embodiment is operated in the following manner. That is to say, a bias current is caused to flow through the semiconductor layer 8 including the light emitting layer 8b, so that light from ultraviolet light to near-ultraviolet light or purple light having a wavelength of approximately 350 to 400 nm is emitted by the light emitting layer 8b, and light from ultraviolet light to near-ultraviolet light or purple light is extracted to the outside of the light emitting element.

Here, in the foregoing embodiment, the n-type is taken as the first conductive-type, and the p-type is taken as the second conductive-type, but the p-type may be taken as the first conductive-type, and the n-type may be taken as the second conductive-type.

### Second Embodiment

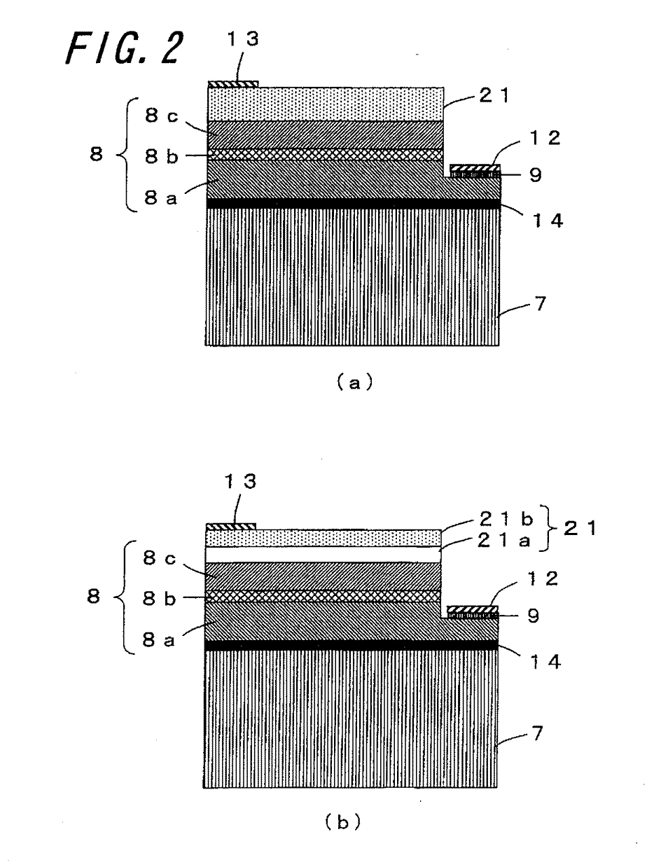

FIGS. 2(a) and 2(b) are schematic cross-sectional views showing other examples of the light emitting element (light emitting diode: LED) of this embodiment. The light emitting element of this embodiment includes the semiconductor layer 8 in which the first conductive-type gallium nitride-based compound semiconductor layer 8a, the light emitting layer 8b composed of a gallium nitride-based compound semiconductor, and the second conductive-type gallium nitride-based compound semiconductor layer 8c are laminated, and a transparent conductive layer 21 that is formed on a main surface of the semiconductor layer 8 and that has a refractive index decreasing in the thickness direction thereof from the side of the semiconductor layer 8.

With the above-described configuration, a change in the refractive index can be made gradual compared with the case in which the refractive index of the transparent conductive layer is constant and the surface of the transparent conductive layer is formed so as to have a concavity and convexity shape as in conventional examples. As a result, the reflection of light at an interface between media having different refractive indexes is reduced, and the light extraction efficiency can be improved.

The refractive index of the transparent conductive layer 21 is becoming lower in the thickness direction thereof from the side of the semiconductor layer 8. Here, as means for having the refractive index becoming lower, means for having the porosity becoming higher (increasing the content of air having a refractive index of approximately 1) in the thickness direction thereof from the side of the semiconductor layer 8, means for changing the material such that the refractive index is becoming lower in the thickness direction thereof from the side of the semiconductor layer 8, means for adding another component such that the refractive index is becoming lower in the thickness direction thereof from the side of the semiconductor layer 8, and the like can be used.

In this embodiment, as preferable means, means for having the porosity of the transparent conductive layer 21 becoming higher (increasing the content of air having a refractive index of approximately 1) in the thickness direction thereof from the side of the semiconductor layer 8 is used. In this case, the refractive index of the transparent conductive layer 21 is gradually becoming lower in the thickness direction. As a result, the refractive index can be gradually becoming lower in the thickness direction in the entire transparent conductive layer 21 and can be close to the refractive index of air, the reflection of light at an interface between media having different refractive indexes is reduced, and the light extraction efficiency can be improved.

In the case where the transparent conductive layer 21 is made of a single layer, the thickness is preferably 0.05 to 1 μm in order to gradually lower the refractive index across the whole layer in the thickness direction. When the thickness of the transparent conductive layer 21 is 0.05 to 1 μm, the refractive index can be easily gradually becoming lower in the thickness direction. Furthermore, the absorption of light by the transparent conductive layer 21 can be suppressed, and a decrease in the light extraction efficiency can be suppressed.

It is preferable that the material of the transparent conductive layer 21 is oxide of at least one of zinc, indium, tin, and magnesium. In this case, the transparent conductive layer 21 has a high transmission from ultraviolet light to blue light, and has good ohmic contact with a p-type gallium nitride-based compound semiconductor layer.

More specifically, the transparent conductive layer 21 is preferably made of a metal oxide-based substance, such as indium tin oxide (ITO), stannic oxide (SnO₂), zinc oxide (ZnO), or the like. Among these substances, indium tin oxide (ITO) is particularly preferable because the transmission from ultraviolet light to blue light is high, and the ohmic contact with the p-type gallium nitride-based compound semiconductor layer 8c is good. The transparent conductive layer 21 can be formed using an electron-beam evaporation method or a sol-gel method.

Furthermore, in the case where the formation is performed using an electron-beam evaporation method, the refractive index of the ITO layer can be controlled by a method in which the temperature of the substrate 7 is controlled in a state where oxygen is not introduced from the outside. Accordingly, the refractive index can be gradually changed by gradually increasing the temperature of the substrate 7 when forming the ITO layer from the initial stage to the end stage in the formation. Here, the ITO layer is reduced during evaporation, and thus, an oxidation treatment is necessary after the formation of the layer. Furthermore, in the case where the ITO layer is formed by a sol-gel method, a method can be used in which the sintering temperature is controlled. Accordingly, the refractive index can be gradually changed by gradually reducing the sintering temperature when forming the ITO layer from the initial stage to the end stage in the formation.

Furthermore, it is preferable that the transparent conductive layer 21 is made of an aggregate of conductive fine particles. In this case, the size of pores (the size of gaps between the conductive fine particles) and the porosity can be controlled by controlling the shape and the size of the conductive fine particles.

Generally, the transparent conductive layer 21 composed of an ITO layer or the like is made of an aggregate of conductive fine particles, and is formed by an electron-beam evaporation method, a sol-gel method, or the like. The shape and the size of the conductive fine particles can be controlled by a method in which the temperature is controlled as described above.

Furthermore, it is preferable that the transparent conductive layer 21 is made of an aggregate of nanowire-shaped crystals. In this case, as in the case where the transparent conductive layer 21 is made of an aggregate of conductive fine particles, the size of pores (the size of gaps between the nanowire-shaped crystals) and the porosity can be controlled by controlling the shape, the size, and the number (density) of the nanowire-shaped crystals.

The aggregates of conductive fine particles and nanowire-shaped crystals are formed in the following manner.

In the case where the aggregate of conductive fine particles is formed by an electron-beam evaporation method, in a state where the temperature of the substrate 7 is increased without introducing a gas, electron beam evaporation of the ITO layer is performed when the transparent conductive layer (ITO layer) 21 is formed. Accordingly, anisotropy appears in the crystal growth rate of metal oxide crystals forming the ITO layer, the metal oxide crystals have a large aspect ratio, and thus, gaps are formed when the metal oxide crystals are deposited. In the case where the size of the gaps is the wavelength of light or smaller, the ratio of the gaps increases as the aspect ratio of metal oxide crystals increases, and thus, the refractive index is becoming lower as the aspect ratio increases. Accordingly, when the temperature of the substrate 7 is continuously increased from the initial stage in the formation of the ITO layer, an ITO layer in which the refractive index is becoming lower in the thickness direction can be obtained.

Moreover, in a state where the aspect ratio is increased, when the layer is formed finally at a temperature of approximately 400° C., the metal oxide crystals are formed into nanowire-shaped crystals having a diameter of 20 nm or less and a length of 500 nm or more. Then, when the size of the gaps between the nanowire-shaped crystals is substantially the same as or not smaller than the wavelength of light, the light is refracted at the gaps, and thus, the transparent conductive layer 21 scatters the light. The thus formed ITO layer is reduced and partially becomes the metal In, and the transmission is lowered. Thus, lastly, an oxidation treatment is performed in an atmospheric atmosphere at 600° C. for approximately 5 minutes.

Here, the aggregate of nanowire-shaped crystals is such that a large number of nanowire-shaped crystals grow and are deposited so that their longitudinal directions lie in random directions.

In the case where the aggregate of conductive fine particles is formed by a sol-gel method, gaps between the conductive fine particles are generally changed to form a denser layer as the sintering temperature increases. Accordingly, when the sintering temperature is gradually reduced from the initial stage in the formation, the gaps between the conductive fine particles can be gradually increased in the thickness direction.

Accordingly, in the case where a first transparent conductive layer 21a is formed by a sol-gel method, when the size of gaps between the conductive fine particles is increased within a range in which the size of the gaps is the wavelength of light or smaller, the refractive index of the first transparent conductive layer 10 can be becoming lower in the thickness direction. Furthermore, in the case where a second transparent conductive layer 21b is formed by a sol-gel method, when the sintering temperature is further reduced, the size of the gaps is larger than the wavelength of the light, which is preferable because light is scattered.

Also, in this case, the first and second transparent conductive layers 21a and 21b can be successively formed by a sol-gel method.

Furthermore, as shown in FIG. 2(b), the transparent conductive layer 21 preferably includes the first transparent conductive layer 21a that is formed on the side of the semiconductor layer 8 and that is made of an aggregate of conductive fine particles and the second transparent conductive layer 21b that is formed on the first transparent conductive layer 21a and that is made of an aggregate of nanowire-shaped crystals.

As described above, the transparent conductive layer 21 including the first transparent conductive layer 21a and the second transparent conductive layer 21b can be formed by continuously increasing the temperature of the substrate 7 during the formation of the transparent conductive layer 21 by an electron-beam evaporation method. For example, the first transparent conductive layer 21a and the second transparent conductive layer 21b composed of an ITO layer can be formed by setting the temperature of the substrate 7 to room temperature at the initial stage of the formation and to 400° C. at the end stage of the formation. Then, after the formation, an oxidation treatment is performed in an atmospheric atmosphere at 600° C. for approximately 5 minutes. In this case, directly after the formation of the first transparent conductive layer 21a, the second transparent conductive layer 21b can be successively formed.

In the configuration in FIG. 2(b), the first transparent conductive layer 21a is formed on the p-type gallium nitride-based compound semiconductor layer 8c, but a metal layer made of Ni or the like may be interposed between the p-type gallium nitride-based compound semiconductor layer 8c and the first transparent conductive layer 21a in order to reduce the contact resistance.

On one main surface (upper surface in FIG. 2) of the semiconductor layer 8, the first transparent conductive layer 21a in which the refractive index is becoming lower from that one main surface in the thickness direction and the second transparent conductive layer 21b made of an aggregate of nanowire-shaped crystals for scattering light are sequentially formed. However, in order to easily perform the formation process, the first transparent conductive layer 21a may be a dense layer in which the refractive index is constant (e.g., in the case of ITO, n is approximately 2.0). Also in this case, the light extraction efficiency is improved due to the light scattering effect obtained by the second transparent conductive layer 21b. Here, in FIGS. 2(a) and 2(b), reference numeral 14 denotes a reflective layer at which light reflected at an interface between the second transparent conductive layer 21b and outside air into the semiconductor layer 8 is efficiently reflected again to one main surface of the semiconductor layer 8.

The thickness of the first transparent conductive layer 21a is preferably 50 nm to 1 μm. When the thickness of the first transparent conductive layer 21a is 50 nm to 1 μm, a change in the refractive index easily occurs in the thickness direction. Furthermore, absorption of light by the first transparent conductive layer 21a can be suppressed, and a decrease in the light extraction efficiency can be suppressed.

The second transparent conductive layer 21b is made of a material that is the same as or different from the first transparent conductive layer 21a. The thickness of the second transparent conductive layer 21b is preferably 100 nm to 5 μm. When the thickness of the second transparent conductive layer 21b is 100 nm to 5 μm, light can be sufficiently scattered. Furthermore, absorption of light by the second transparent conductive layer 21b can be suppressed, and the formation time can be further shortened to improve the productivity.

As the reflective layer 14, for example, distributed bragg reflectors (DBR) are preferably used in which a plurality of layers having a high refractive index and layers having a low refractive index are alternately laminated, and thus, the reflection is intensified by the layers having a high refractive index and the layers having a low refractive index through bragg reflection due to light interference effects. More specifically, when a DBR periodic structure in which 20 pairs of GaN layers having a thickness of 41.5 nm and Al_{0.52}Ga_{0.48}N layers having a thickness of 38.5 nm are laminated is formed, a reflective layer 14 having a very good reflectance ratio for light having an emission wavelength of 400 nm can be obtained.

The semiconductor layer 8 is formed through epitaxial growth on the substrate 7 made of sapphire, SiC, gallium nitride-based compound semiconductor (GaN, etc.), or the like, via a buffer layer and the reflective layer 14 made of a gallium nitride-based compound semiconductor, such as a GaN layer. Light proceeding toward the substrate 7 is reflected by the reflective layer 14 toward the transparent conductive layer 21, which is in a light extraction direction, and thus, light can be effectively condensed in the light extraction direction.

In the semiconductor layer 8 of this embodiment, the light emitting layer 8b is held between the n-type gallium nitride-based compound semiconductor layer 8a and the p-type gallium nitride-based compound semiconductor layer 8c. For example, the n-type gallium nitride-based compound semiconductor layer 8a is a laminated member in which a GaN layer as a first n-type cladding layer and an In_{0.02}Ga_{0.98}N layer as a second n-type cladding layer are laminated. The thickness of the n-type gallium nitride-based compound semiconductor layer 8a is approximately 2 μm to 3 μm.

Furthermore, for example, the p-type gallium nitride-based compound semiconductor layer 8c is a laminated member in which an Al_{0.2}Ga_{0.8}N layer as a first p-type cladding layer, an Al_{0.15}Ga_{0.85}N layer as a second p-type cladding layer, and a GaN layer as a p-type contact layer are laminated. The thickness of the p-type gallium nitride-based compound semiconductor layer 8c is approximately 200 nm to 300 nm.

Furthermore, for example, the light emitting layer 8b has a multi-quantum well (MQW) structure in which In_{0.01}Ga_{0.99}N layers as barrier layers having a wide forbidden band width and In_{0.11}Ga_{0.89}N layers as well layers having a narrow forbidden band width are alternately and regularly laminated, for example, three times in a repetitive manner. The thickness of the light emitting layer 8b is approximately 25 nm to 150 nm.

The material of the n-type conductive layer 9 is preferably a material that reflects light emitted by the light emitting layer 8b without loss and that obtains good ohmic contact with the n-type gallium nitride-based compound semiconductor layer 8a. Examples of this sort of material include aluminum (Al), titanium (Ti), nickel (Ni), chromium (Cr), indium (In), tin (Sn), molybdenum (Mo), silver (Ag), gold (Au), niobium (Nb), tantalum (Ta), vanadium (V), platinum (Pt), lead (Pb), beryllium (Be), indium oxide (In₂O₃), a gold-silicon (Au—Si) alloy, a gold-germanium (Au—Ge) alloy, a gold-zinc (Au—Zn) alloy, and a gold-beryllium (AuBe) alloy. Among these substances, aluminum (Al) or silver (Ag) is preferable because the reflection ratio for light from blue light (wavelength 450 nm) to ultraviolet light (wavelength 350 nm), which is emitted by the light emitting layer 8b, is high. Furthermore, aluminum (Al) is particularly preferable also in view of the ohmic contact with the re-type gallium nitride-based compound semiconductor layer 8a. Furthermore, a plurality of layers selected from among the above-listed substances may be laminated.

Furthermore, an n-side pad electrode 12 and a p-side pad electrode 13 that are connected to conducting wires and the like to establish an electrical connection with the outside are respectively arranged on the n-type conductive layer 9 and the second transparent conductive layer 21b. As these electrodes, for example, a titanium (Ti) layer or a laminated member in which a gold (Au) layer is laminated on a titanium (Ti) layer functioning as a base layer may be used.

### Third Embodiment

Furthermore, the light emitting element of this embodiment includes a light emitting portion, and a porous transparent conductive layer that is formed on a light-radiating surface of the light emitting portion and that has a porosity becoming higher in the thickness direction thereof from the side of the light emitting portion. With this configuration, the refractive index of the transparent conductive layer is gradually becoming lower in the thickness direction thereof from the side of the light emitting portion. As a result, the refractive index of the transparent conductive layer is gradually becoming lower across the whole layer in the thickness direction and can be close to the refractive index of air, the reflection of light at an interface between media having different refractive indexes is reduced, and the light extraction efficiency can be improved.

The light emitting portion may be various light emitting portions, such as a semiconductor layer portion in a semiconductor laser, a light emitting portion of an organic EL, a light emitting portion of a plasma light emitting device, a light emitting portion of a liquid crystal display device; or the like. Accordingly, the light emitting element in this case is a semiconductor laser, an organic EL, a plasma light emitting device, a liquid crystal display device, or the like.

### Fourth Embodiment

Furthermore, the light emitting element of this embodiment includes a light emitting portion, and a transparent conductive layer that is formed on a light-radiating surface of the light emitting portion and that has a refractive index becoming lower in the thickness direction thereof from the side of the light emitting portion. With this configuration, a change in the refractive index can be made gradual compared with the case in which the refractive index of the transparent conductive layer is constant and the surface of the transparent conductive layer is formed so as to have a concavity and convexity shape as in conventional examples. As a result, the reflection of light at an interface between media having different refractive indexes is reduced, and the light extraction efficiency can be improved.

The light emitting portion may be various light emitting portions, such as a semiconductor layer portion in a semiconductor laser, a light emitting portion of an organic EL, a light emitting portion of a plasma light emitting device, a light emitting portion of a liquid crystal display device, or the like. Accordingly, the light emitting element in this case is a semiconductor laser, an organic EL, a plasma light emitting device, a liquid crystal display device, or the like.

### <<Illumination Device>>

Furthermore, a light emitting element of the foregoing embodiments can be applied to an illumination device. The illumination device includes a light emitting element of the foregoing embodiments, and at least one of a fluorescent substance and a phosphorescent substance that emit light based upon receiving light emitted by the light emitting element. With this configuration, an illumination device having a high brightness and a high illuminance can be obtained. This illumination device may be formed by covering or containing the light emitting element of this embodiment in a transparent resin or the like, wherein the transparent resin or the like may contain a fluorescent substance or a phosphorescent substance. Accordingly, light from ultraviolet light to near-ultraviolet light of the light emitting element can be converted by the fluorescent substance or the phosphorescent substance into white light or the like. Furthermore, in order to improve the light-condensing properties, a light-reflecting member, such as a concave mirror or the like, may be provided on the transparent resin or the like. This sort of illumination device consumes less electrical power and is smaller than a conventional fluorescent lamp, and thus, is effective as a small illumination device having a high brightness.

### Example 1

Hereinafter, examples of the light emitting element of this embodiment will be described.

The light emitting element in FIG. 1(a) was produced in the following manner. The following treatment was performed in each of the formation regions for light emitting elements on the substrate (mother substrate) 7 made of sapphire having a plurality of formation regions.

First, as a buffer layer (not shown), a first GaN layer having a thickness of 20 nm and a second GaN layer having a thickness of 2 μm were formed. The first GaN layer was formed at a low temperature of approximately 500° C. and subjected to an annealing treatment at approximately 700° C. The second GaN layer was formed at a temperature of approximately 1100° C. The first GaN layer formed at a low temperature was in an amorphous state, and thus, strain due to a difference in lattice constant and a difference in coefficient of thermal expansion between the substrate 7 and the semiconductor layer 8 was effectively alleviated.

Next, as the reflective layer 14, twenty pairs of GaN layers having a thickness of 41.5 nm and Al_{0.52}Ga_{0.48}N layers having a thickness of 38.5 nm were laminated, and thus, a reflective layer 14 having a DER (distributed bragg reflector) periodic structure was formed.

Next, an Si-doped n-type GaN layer having a thickness of 2 μm as the n-type gallium nitride-based compound semiconductor layer 8a, and a multi-quantum well (MQW) layer having a thickness of 30 nm as the light emitting layer 8b in which InGaN layers and GaN layers were alternately laminated were sequentially formed by a metal organic vapor phase epitaxy (MOVPE) method.

Next, as the p-type gallium nitride-based compound semiconductor layer 8c, an Mg-doped p-type AlGaN cap layer having a thickness of 20 nm, an Mg-doped p-type AlGaN cladding layer having a thickness of 200 nm, and an Mg-doped p-type GaN contact layer having a thickness of 10 nm were sequentially formed by an MOVPE method. Accordingly, the semiconductor layer 8 was formed.

Next, the transparent conductive layer 20 was produced in the following manner. First, the temperature of the substrate 7 was set to room temperature, and an ITO layer was deposited to a thickness of 100 nm without introducing an oxygen gas. Subsequently, the ITO layer was further deposited to a thickness of 300 nm while the temperature of the substrate 7 was linearly increased to 200° C., and a transparent conductive layer 20 having a total thickness of 400 nm was formed. Subsequently, an annealing treatment was performed in an atmospheric atmosphere at 600° C. for 5 minutes.

Next, in order to form the n-type conductive layer 9 on an exposed portion of the n-type gallium nitride-based compound semiconductor layer 8a, part of the light emitting element was etched and removed until the n-type gallium nitride-based compound semiconductor layer 8a was exposed by a reactive ion etching (RTE) method. Next, a metal layer in which a titanium (Ti) layer and an aluminum (Al) layer were laminated was formed as the n-type conductive layer 9 on the exposed portion in the outer peripheral portion of the upper surface of the n-type gallium nitride-based compound semiconductor layer 8a.

Lastly, the n-side pad electrode 12 made of a metal layer in which a titanium (Ti) layer and a gold (Au) layer were laminated was formed on part of the surface of the n-type conductive layer 9. Furthermore, the p-side pad electrode 13 made of a metal layer in which a titanium (Ti) layer and a gold (Au) layer were laminated was formed on the transparent conductive layer 20.

Lastly, dicing was performed such that the resultant was cut into a plurality of formation regions for light emitting elements, and thus, the individual light emitting elements were separated from each other, and light emitting elements in the shape of rectangular solids were produced.

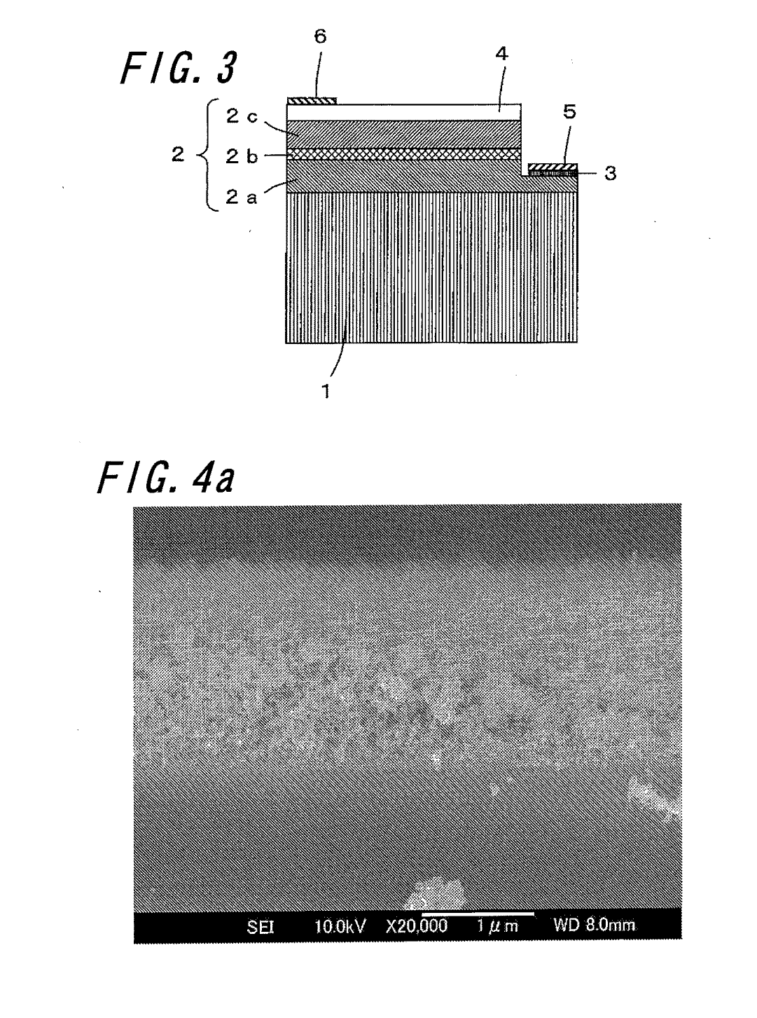

As a comparative example, a light emitting element as in FIG. 3 having the same configuration as in Example 1 except that the transparent conductive layer 20 was uniformly dense was produced.

A current was caused to flow through these light emitting elements, and the light emission intensity of the light emitting elements was measured in integrating spheres enclosing the light emitting elements. The light extraction efficiency of the light emitting element of Example 1 was 1.5 times that of the light emitting element of the comparative example.

### Example 2

The light emitting element in FIG. 1(b) was produced in the following manner. The reflective layer 14 and the semiconductor layer 8 were formed on the substrate (mother substrate) 7 made of sapphire having a plurality of formation regions for light emitting elements as in Example 1

Next, as the p-type gallium nitride-based compound semiconductor layer 8c, an Mg-doped p-type AlGaN cap layer having a thickness of 20 nm, an Mg-doped p-type AlGaN cladding layer having a thickness of 200 nm, and an Mg-doped p-type GaN contact layer having a thickness of 10 nm were sequentially formed by an MOVPE method. Accordingly, the semiconductor layer 8 was formed.

Next, the first transparent conductive layer 10 was produced in the following manner. First, the temperature of the substrate 7 was set to room temperature, and an ITO layer was deposited to a thickness of 100 nm without introducing an oxygen gas. Subsequently, the ITO layer was further deposited to a thickness of 300 nm while the temperature of the substrate 7 was linearly increased to 200° C., and a first transparent conductive layer 10 having a total thickness of 400 nm was formed. Then, the temperature of the substrate 7 was increased to 400° C., a nanowire crystal-like ITO layer was deposited to a thickness of 1 μm, and thus, a second transparent conductive layer 11 was formed. Subsequently, an annealing treatment was performed in an atmospheric atmosphere at 600° C. for 5 minutes.

Next, the n-type conductive layer 9, the n-side pad electrode 12, and the p-side pad electrode 13 were formed as in Example 1.

Lastly, dicing was performed such that the resultant was cut into a plurality of formation regions for light emitting elements, and thus, the individual light emitting elements were separated from each other, and light emitting elements in the shape of rectangular solids were produced.

A current was caused to flow through the light emitting element of Example 2, and the light emission intensity of the light emitting element was measured in an integrating sphere enclosing the light emitting element. The light extraction efficiency of the light emitting element of Example 2 was 1.8 times that of the light emitting element of the comparative example.

1. A light emitting element comprising:
a semiconductor layer in which a first conductive-type gallium nitride-based compound semiconductor layer, a light emitting layer composed of a gallium nitride-based compound semiconductor, and a second conductive-type gallium nitride-based compound semiconductor layer are laminated; and
a porous transparent conductive layer that is formed on a main surface of the semiconductor layer and that has a porosity becoming higher in a thickness direction thereof from a side of the semiconductor layer.

2. The light emitting element of claim 1, wherein the transparent conductive layer is made of an aggregate of nanowire-shaped crystals.

3. The light emitting element of claim 1, wherein the transparent conductive layer comprises a first transparent conductive layer that is formed on the side of the semiconductor layer and that is made of an aggregate of conductive fine particles, and a second transparent conductive layer that is formed on the first transparent conductive layer and that is made of an aggregate of nanowire-shaped crystals.

4. The light emitting element of claim 3, wherein a porosity of the first transparent conductive layer is becoming higher in the thickness direction thereof from the side of the semiconductor layer.

5. The light emitting element of any one of claim 1, wherein the transparent conductive layer is made of oxide of at least one of zinc, indium, tin, and magnesium.

6. An illumination device, comprising:
the light emitting element of claim 1, and
at least one of a fluorescent substance and a phosphorescent substance that emit light based upon receiving light emitted by the light emitting element.

7. A light emitting element, comprising:
a semiconductor layer in which a first conductive-type gallium nitride-based compound semiconductor layer, a light emitting layer composed of a gallium nitride-based compound semiconductor, and a second conductive-type gallium nitride-based compound semiconductor layer are laminated; and
a transparent conductive layer that is formed on a main surface of the semiconductor layer and that has a refractive index becoming lower in a thickness direction thereof from a side of the semiconductor layer.

8. The light emitting element of claim 7, wherein a porosity of the transparent conductive layer is becoming higher in the thickness direction thereof from the side of the semiconductor layer.

9. The light emitting element of claim 7, wherein the transparent conductive layer is made of an aggregate of conductive fine particles.

10. The light emitting element of claim 7, wherein the transparent conductive layer is made of an aggregate of nanowire-shaped crystals.

11. The light emitting element of claim 7, wherein the transparent conductive layer comprises a first transparent conductive layer that is formed on the side of the semiconductor layer and that is made of an aggregate of conductive fine particles, and a second transparent conductive layer that is formed on the first transparent conductive layer and that is made of an aggregate of nanowire-shaped crystals.

12. The light emitting element of claim 11, wherein a porosity of the first transparent conductive layer is becoming higher in the thickness direction thereof from the side of the semiconductor layer.

13. The light emitting element of claim 7, wherein the transparent conductive layer is made of oxide of at least one of zinc, indium, tin, and magnesium.

14. A light emitting element, comprising:
a light emitting portion; and
a porous transparent conductive layer that is formed on a light-radiating surface of the light emitting portion and that has a porosity becoming higher in a thickness direction thereof from a side of the light emitting portion.

15. A light emitting element, comprising:
a light emitting portion; and
a transparent conductive layer that is formed on a light-radiating surface of the light emitting portion and that has a refractive index becoming lower in a thickness direction thereof from a side of the light emitting portion.

16. An illumination device, comprising:
the light emitting element of claim 7, and
at least one of a fluorescent substance and a phosphorescent substance that emit light based upon receiving light emitted by the light emitting element.
